(19) United States
(12) Patent Application Publication
(10) Pub. No.: US 2008/0020610 A1
(43) Pub. Date: Jan. 24, 2008

(54) Printed circuit board

(75) Inventor: Hyuck-Dong Kwon, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/826,976

(22) Filed: Jul. 19, 2007

(30) Foreign Application Priority Data
Jul. 24, 2006 (KR) 10-2006-0069386

(51) Int. Cl. H05K 1/00

(52) U.S. Cl. 439/79

(57) ABSTRACT

A printed circuit board is disclosed. An printed circuit board which includes a board part, on one side of which a motor is mounted; and a reinforcement plate joined to the other side of the board part, where a bent portion is formed in at least one end portion of the reinforcement plate, can increase strength and prevent resonance by joining a reinforcement plate having a bent portion at the end portions to a board part.

### CROSS-REFERENCE TO RELATED APPLICATIONS

This application claims the benefit of Korean Patent Application No. 10-2006-0069386 filed with the Korean Intellectual Property Office on Jul. 24, 2006, the disclosure of which is incorporated herein by reference in its entirety.

### BACKGROUND

1. Technical Field

The present invention relates to a printed circuit board (PCB).

2. Description of the Related Art

In a printed circuit board having a mounted motor, the rotational vibration of the rotor is delivered to the printed circuit board via the shaft system, and also the vibration due to the electromagnetic force between the permanent magnet and the core stator is delivered to the printed circuit board.

The vibrations generated by the rotation and the electromagnetic force are delivered to the set via the PCB. Here, if the natural frequency of the set is equal to the harmonic forcing frequency of the motor, there is a risk that noise and vibration may be increased due to resonance.

Also, because a PCB is a thin plate, when a motor is mounted on the PCB, bending may be occurred due to the vibrations delivered to the motor.

Because of this bending, an electronic component mounted on a PCB may be put into contact with other members and damaged, or faulty connections may occur between an electronic component and a terminal. Also, there is a risk that a circuit pattern formed on the PCB may be severed, or that the PCB itself may be fractured.

Thus, there are various methods being proposed of increasing the strength of a PCB by changing the material of the PCB or by increasing the thickness of the PCB.

However, such methods do not effectively respond to the trend towards larger PCB's, and the problems of weight and cost still remain.

### SUMMARY

An aspect of the claimed invention is to provide a PCB in which the strength can readily be increased and in which the PCB can be prevented from resonating with the main body on which a motor is equipped, by joining a reinforcement plate having bent portions to the board part.

One aspect of the claimed invention provides a printed circuit board that includes a board part, on one side of which a motor is mounted, and a reinforcement plate joined to the other side of the board part, where a bent portion is formed in at least one end portion of the reinforcement plate.

The reinforcement plate may be made of metal, and the bent portion may include multiple unit bent portions. Here, a part of the unit bent portions may be bent towards one side of the reinforcement plate, while a part of the unit bent portions may be bent towards the other side of the reinforcement plate.

Also, the bent portion may extend at a substantially perpendicular angle to the reinforcement plate.

Another aspect of the claimed invention provides a printed circuit board which includes a board part, on one side of which a motor is mounted, and a reinforcement plate joined to the other side of the board part, where a concave-convex portion is formed in the reinforcement plate.

A cross section of the concave-convex portion may be trapezoidal or rectangular.

Additional aspects and advantages of the present invention will be set forth in part in the description which follows, and in part wilt be obvious from the description, or may be learned by practice of the invention.

### BRIEF DESCRIPTION OF THE DRAWINGS

FIG. 1 is a photograph showing a PCB having a mounted motor according to prior art.

FIG. 2 is a perspective view showing a board part of a PCB.

FIG. 3 is a perspective view showing a reinforcement plate of a PCB according to a first disclosed embodiment of the present invention.

FIG. 4 is a perspective view showing the structure of a PCB according to a second disclosed embodiment of the present invention.

FIG. 5 is a cross-sectional view showing the structure of a PCB according to the second disclosed embodiment of the present invention.

FIG. 6 is a cross-sectional view showing the structure of a PCB according to the third disclosed embodiment of the present invention.

FIG. 7 is a cross-sectional view showing the structure of a PCB according to the fourth disclosed embodiment of the present invention.

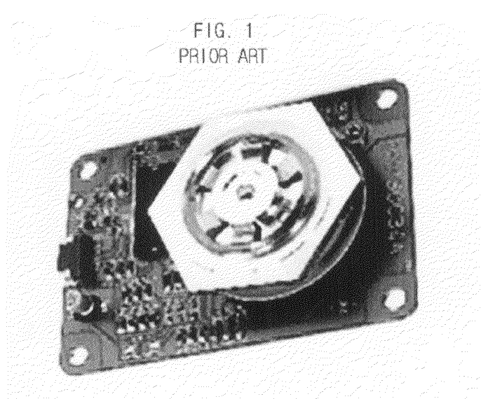

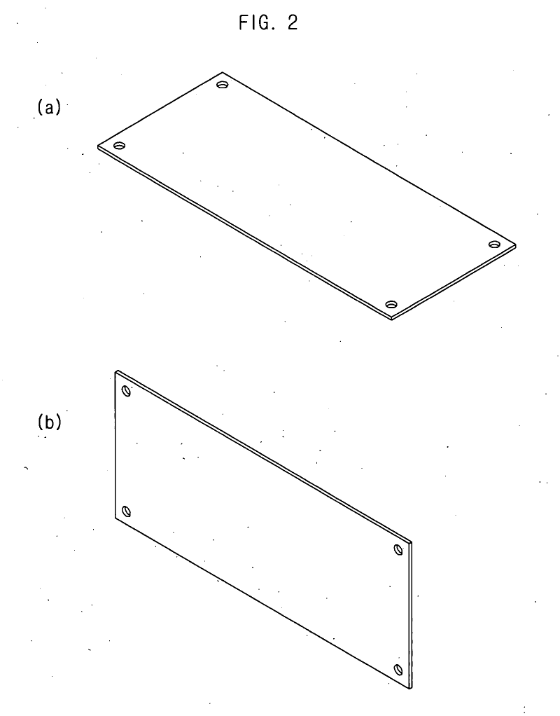

### DETAILED DESCRIPTION

Embodiments of the printed circuit board according to the invention will be described below in more detail with reference to the accompanying drawings, in which those components are rendered the same reference number that are the same or are in correspondence, regardless of the figure number, and redundant explanations are omitted.

Firstly, a PCB according to a first disclosed embodiment of the present invention will be described. The PCB according to the first disclosed embodiment of the present invention can be formed by joining a reinforcement plate that has a bent portion at an end portion to a board part. This PCB thus formed can offer improved stability.

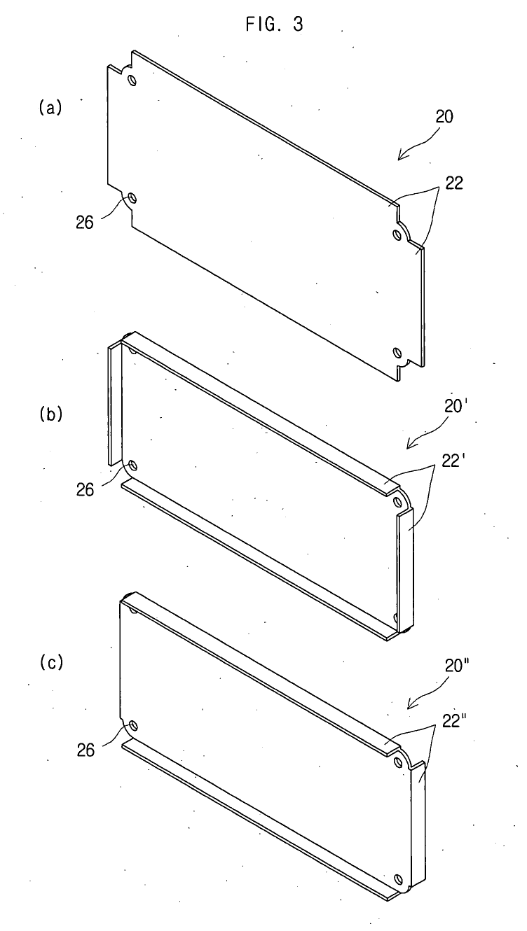

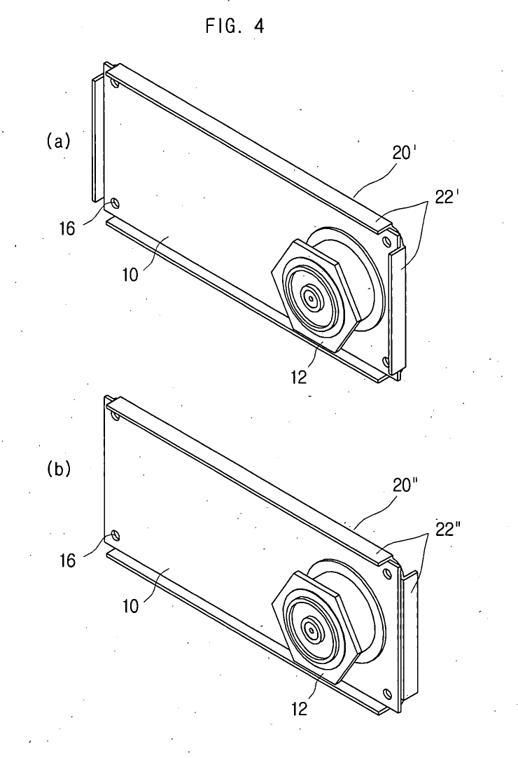

FIG. 3 is a perspective view showing a reinforcement plate of a PCB according to a first disclosed embodiment of the present invention, and FIG. 4 is a perspective view showing the structure of a PCB according to a second disclosed embodiment of the present invention. In FIG. 3 and FIG. 4 are illustrated a board part 10, a motor 12, reinforcement plates 20, 20′, 20″, and bent portions 22, 22′, 22″.

A circuit pattern (not shown) may be formed on one or both sides of the board part 10, and a motor 12 may be mounted on the board part 10. Thus, such functions may be performed as generating or delivering electric signals, as intended by the designer.

When the motor 12 is operated, a vibration is generated. A vibration generated by the motor 12 may be delivered to the board part 10 via a shaft system. Here, the reinforcement plate 20, 20′, 20″ may be joined with the board part 10 to improve strength, since insufficient strength may incur undesirable effects on vibration and precision, etc.

The reinforcement plate 20, 20′, 20″ may be joined with the board part 10 physically or chemically. The board, which serves as a mediator for delivering vibrations due to the rotating of a rotor and vibrations due to the electromagnetic force between a magnet and a core, may support the motor 12 with sufficient strength. The reinforcement plate itself may be made of metal such as iron for high strength.

As the reinforcement plate 20, 20′, 20″ is joined with the board part 10 to improve strength, it may be desirable that the reinforcement plate 20, 20′, 20″ be formed with a shape and size corresponding to those of the board part 10. For example, if the board part is a quadrangle, the reinforcement plate may also be a quadrangle.

To efficiently improve strength using the reinforcement plate, bent portions 22, 22′, 22″ may be formed at the end portions of the reinforcement plate. With the bent portions, the moment of inertia of the reinforcement plate may be increased, as well as the strength of the reinforcement plate. In other words, the bent portions may be formed to maximize strength in a reinforcement plate of the same size.

Similarly, the bent portions may extend at an angle perpendicular to the reinforcement plate.

The bent portions 22′, 22″, referring to FIG. 3, may be formed by fabricating the reinforcement plate 20 in the shape of a dodecagon, as shown in FIG. 3, and then by bending its end portions towards the center of the reinforcement plate 20. The bent portions may be bent in the same direction as shown in FIG. 3(b), or may be bent selectively as shown in FIG. 3(c). This may be changed according to where the PCB according to an embodiment of the present invention is positioned, in consideration of the shapes of the other components, etc., in a product such as a laser printer using the PCB according to the embodiment.

A PCB according to this embodiment may be formed by joining the board part 10 to the reinforcement plate 20′, 20″. When the bent portions are bent in the same direction as shown in FIG. 3(b), the board part may be joined to any portion of the reinforcement plate. This may also be changed according to the shapes of the other elements, etc.

For the joining operation, first holes 16 may be formed in the board part 10 and second hole 26 that correspond with the first holes 16 may be formed in the reinforcement plate 20.

As described with regard to this embodiment, joining a reinforcement plate having a bent portion at the end-portion to a board part can not only increase strength but can also prevent resonance with the product in which the PCB is used (for example, a laser printer).

Resonance may be avoided by ensuring that the natural frequency of the laser printer does not correspond with the harmonic frequency of the PCB. Here, while resonance may be avoided by lowering the natural frequency of the PCB, there may still be a risk of vibration or noise, as the natural frequency range is passed during starting or stopping. Thus, it may be desirable to avoid resonance by increasing the natural frequency of the PCB.

The following table shows the results of IDEAS analysis on the natural frequencies of board parts in PCB's according to prior art and embodiments of the present invention.

Iron plates having a 1 mm thickness and 50*100 size (modulus of elasticity: 200 GPa, Poisson's ratio: 0.29) were analyzed, with the length of the bent portions set to 5 mm.

| | model | | |
|---|---|---|---|
| mode | prior art (Hz) | model 1 (Hz) | model 2 (Hz) |
| 1 | 673 | 1444 | 1443 |
| 2 | 1127 | 2544 | 2544 |
| 3 | 1866 | 2902 | 2852 |
| 4 | 2712 | 3317 | 3311 |
| 5 | 2746 | 4936 | 4867 |

Here, model 1 has the same shape as that of the PCB shown in FIG. 4(a), and model 2 has the same shape as that of the PCB shown in FIG. 4(b).

Referring to the above table, it can be confirmed that the natural frequency has increased almost twofold. Thus, it can be confirmed that a PCB according to this embodiment can prevent resonance and reduce noise and vibration, due to an increased natural frequency.

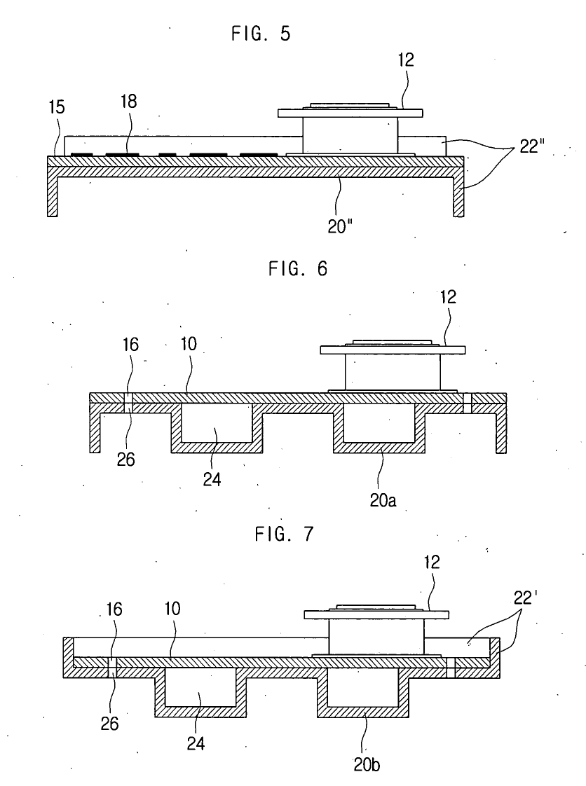

FIG. 5 is a cross-sectional view showing the structure of a PCB according to a second disclosed embodiment of the present invention. In FIG. 5 are illustrated a motor 12, an insulating layer 15, a circuit pattern 18, a reinforcement plate 20″, and bent portions 22″.

A PCB according to this embodiment differs from the PCB according to the first disclosed embodiment described above in that the insulating layer 15 is laminated on the reinforcement plate 20″ and a circuit pattern 18 is formed directly on it.

While the PCB may be formed by fabricating the board part and the reinforcement plate 20″ separately and joining them, it is possible, as in this embodiment, to form the board part and the reinforcement plate as a single body by laminating the insulating layer 15 on the reinforcement plate 20″ and forming the circuit pattern 18 on it.

Next, a PCB according to a third disclosed embodiment of the present invention will be described with reference to FIG. 6.

A PCB according to the third disclosed embodiment of the present invention may be formed by joining a board part 10 with a reinforcement plate 20a having a concave-convex portion 24 to provide improved stability.

FIG. 6 is a cross-sectional view showing the structure of a PCB according to the third disclosed embodiment of the present invention. In FIG. 6 are illustrated a board part 10, a motor 12, a reinforcement plate 20a, and a concave-convex portion 24.

A circuit pattern (not shown) may be formed on one or both sides of the board part 10 and a motor 10 may be mounted on it. This may be used to perform an intended function such as generating or delivering an electric signal.

When the motor 12 is operated, vibrations are generated. The vibrations generated by the motor 12 may be delivered to the board part 10, and the vibrations may be delivered to the main body by way of the board part 10. Thus, the reinforcement plate 20a may be joined with the board part 10 to increase strength.

In addition, a purpose of the reinforcement plate is to firmly support the motor mounted on the main body with sufficient strength. If the strength of the reinforcement plate is not sufficient, defects may be incurred such as optical jitter and vibration. Thus, by bending a plate with uniform thickness, a motor module high in strength may readily be manufactured, and also by adjusting the amount of the bent portions, possible resonance with the main body may readily be avoided.

The reinforcement plate 20a may be joined with the board part and may increase strength to protect the board part. The reinforcement plate 20a may be made of metal such as iron to provide sufficient strength.

Since the reinforcement plate 20a is a component that increases strength by joining with the board part, it may be desirable that the reinforcement plate 20a be formed with a shape and size corresponding to those of the board part 10. For example, if the board part is a quadrangle, the reinforcement plate may also be a quadrangle.

In order to effectively increase strength using the reinforcement plate 20a, a concave-convex portion 24 may be formed in the reinforcement plate 20a. If a concave-convex portion 24 is formed in the reinforcement plate 20a, the moment of inertia of the reinforcement plate 20a may be increased, which may create high strength. In other words, the concave-convex portion may be formed to maximize strength in a reinforcement plate of a certain size.

As shown in FIG. 6, the cross section of the concave-convex portion 24 may be rectangular, because if the contact area between the concave-convex portion and the board part is narrow, fractures may be caused when the load is concentrated. However, considering tolerances in processing, a trapezoidal shape may also be used.

By joining a board part 10 to the reinforcement plate 20a, a PCB according to this embodiment may be formed. For the joining operation, first holes 16 may be formed in the board part 10 and second hole 26 that correspond with the first holes 16 may be formed in the reinforcement plate 20.

The following table shows the results of IDEAS analysis on the natural frequencies of board parts in PCB's according to prior art and embodiments of the present invention.

Iron plates having a 1 mm thickness and 50*100 size (modulus of elasticity: 200 GPa, Poisson's ratio: 0.29) were analyzed, with the length of the bent portions set to 5 mm.

model

| mode | prior art (Hz) | model 3 (Hz) |
|---|---|---|
| 1 | 673 | 2711 |
| 2 | 1127 | 3833 |
| 3 | 1866 | 4515 |
| 4 | 2712 | 4774 |
| 5 | 2746 | 6511 |

Here, model 3 has the same shape as that of the PCB shown in FIG. 6.

Referring to the above table, it can be confirmed that the natural frequency has increased almost threefold. Thus, it can be confirmed that a PCB according to this embodiment can prevent resonance and reduce noise and vibration, due to an increased natural frequency.

Next, a PCB according to a fourth embodiment of the present invention will be described with reference to FIG. 7.

A PCB according to the fourth disclosed embodiment of the present invention may be formed by joining a board part 10 with a reinforcement plate 20a, where the reinforcement plate 20a has a concave-convex portion 24 as well as a bent portion at the end portions to provide improved stability.

FIG. 7 is a cross-sectional view showing the structure of a PCB according to the fourth disclosed embodiment of the present invention. In FIG. 7 are illustrated a board part 10, a motor 12, first holes 16, a reinforcement plate 20b, a bent portion 22′, a concave-convex portion 24, and second holes 26.

Detailed explanations will not be provided for elements that correspond to those of the first and second embodiments described above.

The reinforcement plate 20b may be joined with the board part 10 and may increase strength to protect the board part 10.

In order to increase strength effectively using the reinforcement plate 20b, the concave-convex portion 20b may be formed in the reinforcement plate 20b and the bent portion 22′ may be formed at the end portions of the reinforcement plate 20b. If the concave-convex portion 20b and the bent portion 22′ are formed in the reinforcement plate 20b, the moment of inertia of the reinforcement plate 20b may be increased and may provide high strength. In other words, the concave-convex portion 20b and the bent portion 22′ may be formed to maximize strength in a reinforcement plate of a certain size.

The direction of the bent portion 22′ and the shape of the concave-convex portion 24 may be changed according to design requirements, as described in the first embodiment and the second embodiment.

A PCB according to this embodiment may be formed by joining a board part 10 to the reinforcement plate 20b. For the joining operation, first holes 16 may be formed in the board part 10 and second hole 26 that correspond with the first holes 16 may be formed in the reinforcement plate 20.

According to certain embodiments of the invention as set forth above, by joining a reinforcement plate having a bent portion at the end portions to a board part, the strength of a motor module may be increased and resonance may be avoided as the dynamic characteristics are changed, so that an improved level of stability may be provided without design changes in, for example, a printer equipped with a motor.

Also, by joining a reinforcement plate having a concave-convex portion to a board part, the strength may further be increased, and resonance may readily be avoided, to provide more improved stability.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A printed circuit board comprising:
a board part having a motor mounted on one side thereof; and
a reinforcement plate joined to the other side of the board part,
wherein a bent portion is formed in at least one end portion of the reinforcement plate.

2. A printed circuit board of claim 1, wherein the reinforcement plate is made of metal.

3. A printed circuit board of claim 1, wherein the bent portion comprises a plurality of unit bent portions,
with a part of the unit bent portions bent towards one side of the reinforcement plate,
and a part of the unit bent portions bent towards the other side of the reinforcement plate.

4. A printed circuit board of claim 1, wherein the bent portion extends at a substantially perpendicular angle to the reinforcement plate.

5. A printed circuit board of claim 1, wherein a concave-convex portion is formed in the reinforcement plate.

6. A printed circuit board comprising:
a board part having a motor mounted on one side thereof; and
a reinforcement plate joined to the other side of the board part,
wherein a concave-convex portion is formed in the reinforcement plate.

7. A printed circuit board of claim 6, wherein a cross section of the concave-convex portion is trapezoidal or rectangular.
